(19) United States
(12) Patent Application Publication
(10) Pub. No.: US 2012/0071004 A1
(43) Pub. Date: Mar. 22, 2012

(54) STRESS-ADJUSTING METHOD OF MOS DEVICE

(75) Inventors: Jei-Ming CHEN, Tainan City (TW); Szu-Hao LAI, Kaohsiung City (TW)

(73) Assignee: UNITED MICROELECTRONICS CORP., Hsinchu (TW)

(21) Appl. No.: 12/885,110

(22) Filed: Sep. 17, 2010

(51) Int. Cl. H01L 21/31

(52) U.S. Cl. 438/761; 257/E21.24

(57) ABSTRACT

A stress-adjusting method for use in a manufacturing system of a MOS device is provided. At first, a first stress layer is formed onto a substrate wherein at least two MOSFETs are previously formed on the substrate. The first stress layer overlies an inter-gate region between two adjacent gate regions of the MOSFETs and overlies the two adjacent gate regions. Then, the first stress layer in the inter-gate region is thinned. A second stress layer is further formed onto the substrate to overlie the thinned first stress layer in the inter-gate region to provide the resulting MOS device with satisfactory stress.

### BACKGROUND

1. Technical Field

The present invention relates to a method for adjusting stress, and more particularly to a stress-adjusting method of a MOS device.

2. Description of the Related Art

Mobility enhancement of electrons/holes is one of the keys to improve MOSFET performance in addition to reducing gate width before new material could be found and verified. The mobility can be enhanced up to 4 times for holes and 1.8 times for electrons by providing lattice strain in silicon-based channel and source/drain regions. For example, tensile stress is provided for N-channel MOSFETs to achieve the purpose of enhancing mobility of electrons in channels. On the other hand, compression stress is provided for P-channel MOSFETs to achieve the purpose of enhancing mobility of electron holes in channels.

For providing tensile/compression stress, a silicon nitride (SiN) film exhibiting a high stress feature is applied to a MOS device under a proper deposition condition so as to adjust stress in the channel of the MOS device. The stress effect on mobility also varies with thickness of the SiN film.

Furthermore, Stress Memorization Technique (SMT) is commonly used for adjusting lattice strain in source/drain regions. Hereinafter, a conventional SMT process is illustrated with reference to FIG. 1A through FIG. 1D. As shown in FIG. 1A, implantation into source/drain regions 101 of MOSFETs 10 formed in and exposed from a substrate 1 is performed in order to transform polysilicon into amorphous silicon. Subsequently, a stress film 12 is formed, overlying the substrate 1 with the MOSFETs 10, as shown in FIG. 1B. Spike annealing is then performed, as shown in FIG. 1C, whereby the stress configuration in the source/drain regions rendered by the overlying stress film 12 is memorized. Afterwards, the stress film 12 is removed, as shown in FIG. 1D, so subsequent procedures can be performed on the resulting substrate without the stress film 12.

As mentioned above, the stress effect on mobility varies with thickness of the SiN film. For example, the stress film 12 with 30 nm thickness results in stress of around 1.6˜1.7 GPa. Greater thickness will result in higher stress, but is accompanied by occurrence of seams or voids between MOSFETs. Seams and voids are inferior structure to the device as they might cause difficulty in conducting subsequent manufacturing procedures.

### BRIEF SUMMARY

Therefore, the present invention provides a stress-adjusting method of a MOS device, which provides the resulting MOS device with satisfactory stress while avoiding occurrence of seams or voids.

The present invention provides a stress-adjusting method for use in a manufacturing system of a MOS device, which includes: forming a first stress layer onto a substrate with at least two MOSFETs formed thereon, the first stress layer overlying at least a gate region of the MOSFETs and an inter-gate region between two adjacent gate regions of the MOSFETs; thinning the first stress layer in the inter-gate region; and forming a second stress layer onto the substrate, overlying the thinned first stress layer in the inter-gate region.

The present invention also provides a Stress Memorization Technique (SMT) process for use in a manufacturing system of a MOS device, which includes: forming a first stress layer onto a substrate with at least two MOSFETs formed thereon, the first stress layer overlying a gate region and an inter-gate region of the MOSFETs; thinning the first stress layer; forming a second stress layer onto the substrate, overlying the thinned first stress layer; annealing the substrate after the second stress layer is formed; and removing the first stress layer and the second stress layer.

In an embodiment, the thinning step is implemented with a dry etching process, and the thinning step is controlled to render the thinned first stress layer left in the inter-gate region thicker than the thinned first stress layer left in the gate-region. Each of the first stress layer and the second stress layer is selected from a single silicon nitride layer or a multiple layer composed of silicon oxide and silicon nitride.

Other objectives, features and advantages of the present invention will be further understood from the further technological features disclosed by the embodiments of the present invention wherein there are shown and described preferred embodiments of this invention, simply by way of illustration of modes best suited to carry out the invention.

### BRIEF DESCRIPTION OF THE DRAWINGS

These and other features and advantages of the various embodiments disclosed herein will be better understood with respect to the following description and drawings, in which like numbers refer to like parts throughout, and in which:

FIG. 1A˜FIG. 1D are schematic diagrams illustrating a conventional SMT process; and

FIGS. 2A˜2F are schematic diagrams illustrating a SMT process according to an embodiment of the present invention

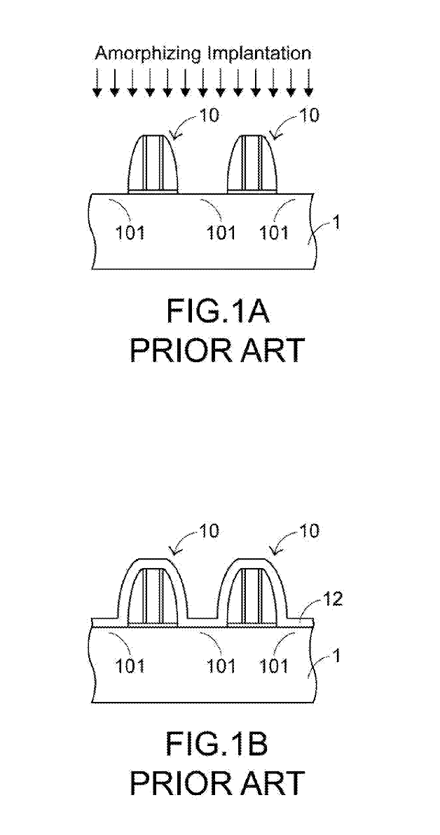

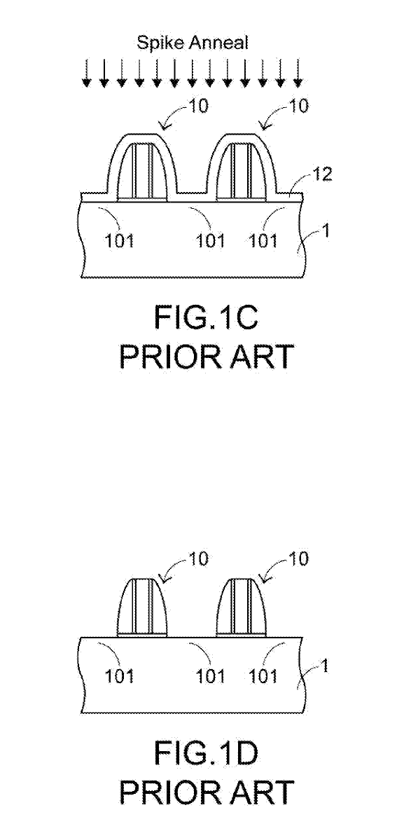

### DETAILED DESCRIPTION

It is to be understood that other embodiment may be utilized and structural changes may be made without departing from the scope of the present invention. Also, it is to be understood that the phraseology and terminology used herein are for the purpose of description and should not be regarded as limiting. The use of “including,” “comprising,” or “having” and variations thereof herein is meant to encompass the items listed thereafter and equivalents thereof as well as additional items.

In order to provide enough stress of a stress film for a MOS device while eliminating undesired seams and voids from the stress film, the stress film is formed by a stress-adjusting method according to the present invention, which involves multi-stage formation of the stress film.

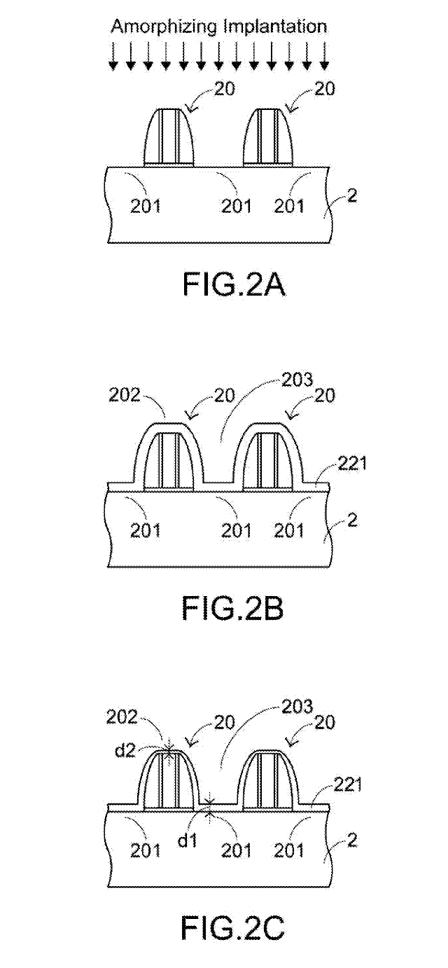

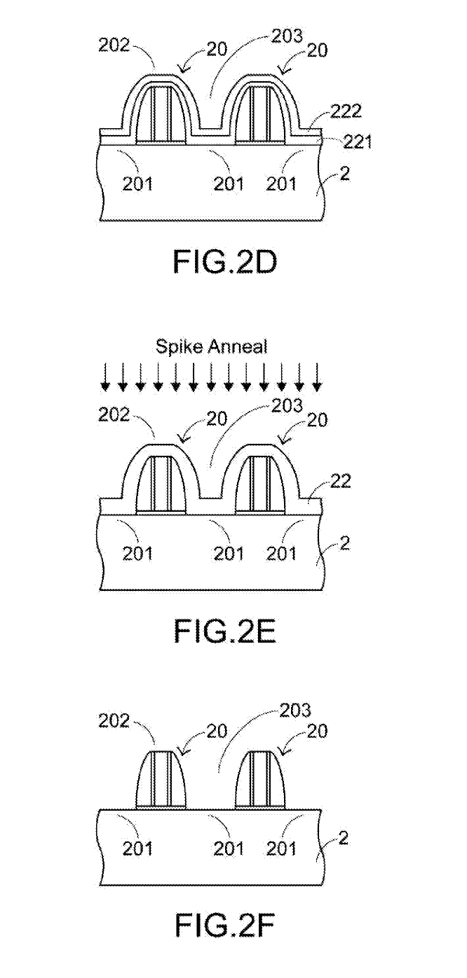

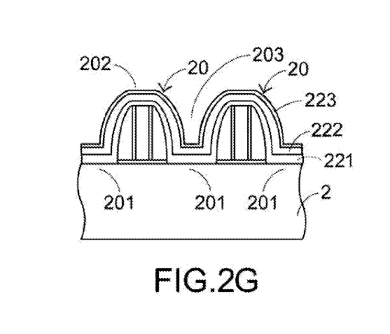

Please refer to FIG. 2A˜FIG.2F, in which a Stress Memorization Technique (SMT) process according to an embodiment of the present invention is illustrated. After MOSFETs 20 are formed in and exposed from a substrate 2 by any proper process, amorphizing implantation into source/drain regions 201 of the MOSFETs is performed, as shown in FIG. 2A, in order to transform polysilicon into amorphous silicon. Subsequently, first deposition is performed to form a first stress layer 221 overlying the substrate 2, as shown in FIG. 2B. In the first deposition, the first stress layer 221 has substantially uniform thickness in the gate region 202 and the inter-gate region 203. Then first etching is performed to partially remove the first stress layer 221. Consequently, the first stress layer 221 in the gate region 202 is thinned. Meanwhile, the first stress layer 221 in the inter-gate region 203 is also thinned but the thickness d1 of the stress layer 221 left in the inter-gate region 203 is greater than the thickness d2 of the first stress layer 221 left in the gate region 202, as shown in FIG. 2C. The thickness control may be implemented by adopting suitable etching process and/or controlling etching conditions. For example, dry etching is one of the options. Since the stress layer 211 in the inter-gate region 203 is somewhat shielded by the sidewall structure during the dry etching, it is etched less than the stress layer 211 in the inter-gate region 203 is. Accordingly, the resulting thickness of the stress layers is differentiated in the gate region 202 and the inter-gate region 203. Likewise, it is understood that the first stress layer 221 in the inter-gate region 203 will not be completely removed at the time when the first stress layer 221 in the gate region 202 is completely removed. After the first etching, second deposition is performed to form a second stress layer 222 overlying the etched first stress layer 221 (FIG. 2D).

If necessary, the second stress layer 222 may be subjected to second etching to be thinned, and the second etching is followed by third deposition. The second etching may be the same as or different from the first etching as long as similar objects of thinning or removing the second stress layer 222 in the gate region 202 while thinning the second stress layer 222 in the inter-gate region 203 to a less extent can be achieved. The deposition and etching of further stress layer may be repetitively performed, depending on practical requirements, e.g. the desired stress level. Then spike annealing is performed, as shown in FIG. 2E, whereby the stress configuration in the source/drain regions rendered by the overlying stress layers 221, 222 is memorized. Afterwards, the stress layers 221, 222 are removed, as shown in FIG. 2F, so subsequent procedures can be performed on the resulting substrate without the stress layers.

In an example, the first deposition and second deposition can be performed by a CVD (chemical vapor deposition), PVD (physical vapor deposition) or spin coating process, and the material of the stress layers can be a single layer of silicon nitride (SiN) or a multi-layer composed of silicon oxide (SiO₂) and silicon nitride (SiN). In the first deposition, the resulting first stress layer 211 has thickness of 100˜150 angstroms (A). The first etching, which can be a dry etching process, is performed in a reacting chamber using a remote plasma source to generate the etchant so as to minimize damage to the surface of the substrate, caused by plasma. The reacting chamber, for example, can be a Siconi™ preclean chamber developed by Applied Materials, USA, and the etchant, for example, can be NH₄F species. It is advantageous to use the Siconi™ preclean chamber in the embodiment of the present invention as the pressure in the chamber need not be reduced to a mTorr level, and instead, several tons would be fine for the etching process. The etching process includes reacting the etchant with the material to be etched to form a solid by-product, and then in-situ annealing or heating the substrate to sublimate/decompose the solid by-product. As a result, 50˜150 A of the first stress layer 211 is etched off. Then in the second deposition, the second stress layer 222 with thickness of 100˜500 A is formed. More specifically, an example of the reacting chamber can be a chamber of a cluster tool, e.g. a Siconi™ preclean chamber included in a ENDURA ALPS ESI PVD system.

By way of multi-stage formation, e.g. deposition-etching-deposition, of the stress film, occurrence of seams and voids in the region between gates can be avoided while relatively thick stress film can be produced. With reasonably thick stress film, satisfactory stress can be exhibited and mobility of the MOS device can be improved.

The above description is given by way of example, and not limitation. Given the above disclosure, one skilled in the art could devise variations that are within the scope and spirit of the invention disclosed herein, including configurations ways of the recessed portions and materials and/or designs of the attaching structures. Further, the various features of the embodiments disclosed herein can be used alone, or in varying combinations with each other and are not intended to be limited to the specific combination described herein. Thus, the scope of the claims is not to be limited by the illustrated embodiments.

1. A stress-adjusting method for use in a manufacturing system of a MOS device, comprising:
forming a first stress layer onto a substrate with at least two MOSFETs formed thereon, the first stress layer overlying at least a gate region of the MOSFETs and an inter-gate region between two adjacent gate regions of the MOSFETs;
thinning the first stress layer in the inter-gate region with a dry etching process to obtain a thinned first stress layer; and
forming a second stress layer onto the substrate, overlying the thinned first stress layer in the inter-gate region.

2. The method according to claim 1, wherein a thickness of the first stress layer is 100˜150 A.

3. The method according to claim 1, wherein 50˜150 A of the first stress layer is removed in the dry etching process.

4. The method according to claim 1 wherein a thickness of the second stress layer is 100˜500 A.

5. (canceled)

6. The method according to claim 1, wherein each of the first stress layer and the second stress layer is selected from a single silicon nitride layer or a multiple layer composed of silicon oxide and silicon nitride.

7. The method according to claim 1, further comprising thinning the second stress layer in the inter-gate region, and forming a third stress layer onto the substrate, overlying the thinned second stress layer in the inter-gate region.

8. A Stress Memorization Technique (SMT) process for use in a manufacturing system of a MOS device, comprising:
forming a first stress layer onto a substrate with at least two MOSFETs formed thereon, the first stress layer overlying a gate region and an inter-gate region of the MOSFETs;
thinning the first stress layer with a dry etching process to obtain a thinned first stress layer;
forming a second stress layer onto the substrate, overlying the thinned first stress layer;
annealing the substrate after the second stress layer is formed; and
removing the thinned first stress layer and the second stress layer.

9. The method according to claim 8, wherein the dry etching process is controlled to render the thinned first stress layer left in the inter-gate region thicker than the thinned first stress layer left in the gate-region.

10. (canceled)

11. The method according to claim 8, wherein the first stress layer is formed by a CVD, PVD or spin coating process.

12. The method according to claim 11, wherein a thickness of the first stress layer is 100˜150 A.

13. (canceled)

14. The method according to claim 8, wherein 50˜150 A of the first stress layer is removed in the dry etching process.

15. The method according to claim 8, wherein the second stress layer is formed by a CVD, PVD or spin coating process.

16. The method according to claim 15, wherein a thickness of the second stress layer is 100˜500 A.

17. The method according to claim 8, wherein each of the first stress layer and the second stress layer is selected from a single silicon nitride layer or a multiple layer composed of silicon oxide and silicon nitride.

18. The method according to claim 8, further comprising thinning the second stress layer in the inter-gate region to obtain a thinned second stress layer, and forming a third stress layer onto the substrate, overlying the thinned second stress layer in the inter-gate region.
